(19) United States
(12) Patent Application Publication
(10) Pub. No.: US 2023/0402520 A1
(43) Pub. Date: Dec. 14, 2023

(54) STAIRCASE STACKED FIELD EFFECT TRANSISTOR

(71) Applicant: INTERNATIONAL BUSINESS MACHINES CORPORATION, ARMONK, NY (US)

(72) Inventors: Sanjay C. Mehta, San Jose, CA (US); Ruilong Xie, Niskayuna, NY (US); Shogo Mochizuki, Mechanicville, NY (US); Min Gyu Sung, Latham, NY (US)

(21) Appl. No.: 17/806,340

(22) Filed: Jun. 10, 2022

(51) Int. Cl. H01L 29/423; H01L 27/088; H01L 29/417; H01L 21/822

(52) U.S. Cl. CPC H01L 29/42392; H01L 27/088; H01L 29/41775; H01L 21/8221

(57) ABSTRACT

A semiconductor device is provided. The semiconductor device includes a semiconductor device comprising: a bottom field effect transistor (FET); a top FET stacked over the bottom FET, where the top FET has a smaller active area than the bottom FET; a bottom gate formed in contact with the bottom FET; a top gate formed in contact with the top FET; and a bottom contact formed adjacent to the top gate, wherein an inner spacer is formed between the bottom contact and the top gate.

### BACKGROUND

The present disclosure relates to fabrication methods and resulting structures for semiconductor devices. More specifically, the present disclosure relates to fabrication methods and resulting structures for field effect transistors (FETs) with stacked n-type and p-type nanosheets for complementary metal oxide semiconductor (CMOS) technologies.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased. Nanosheets generally refer to two-dimensional nanostructures with a thickness range on the order of about 1 nanometer (nm) to about 100 nm, and they can facilitate the fabrication of non-planar semiconductor devices having a reduced footprint compared to conventional planar-type semiconductor devices. For example, nanosheet transistors, in contrast to conventional planar FETs, include a gate stack that wraps around the full perimeter of multiple stacked nanosheet channel regions for a reduced device footprint and improved control of channel current flow. Nanosheet transistor configurations may enable fuller depletion in the nanosheet channel regions and reduce short-channel effects. Accordingly, nanosheets and nanowires are seen as feasible options for reducing the footprints of semiconductor transistor devices to 7 nanometers or less.

### SUMMARY

Embodiments of the present disclosure relate to a semiconductor device. The semiconductor device includes a semiconductor device comprising: a bottom field effect transistor (FET); a top FET stacked over the bottom FET, where the top FET has a smaller active area than the bottom FET; a bottom gate formed in contact with the bottom FET; a top gate formed in contact with the top FET; and a bottom contact formed adjacent to the top gate, wherein an inner spacer is formed between the bottom contact and the top gate.

Embodiments of the present disclosure relate to a method of manufacturing a semiconductor device. The method includes forming a bottom field effect transistor (FET); forming a top FET stacked over the bottom FET, where the top FET has a smaller active area than the bottom FET; forming a bottom gate in contact with the bottom FET; forming a top gate in contact with the top FET; and forming a bottom contact adjacent to the top gate, wherein an inner spacer is formed between the bottom contact and the top gate.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of a semiconductor device at an intermediate stage of the fabrication process and taken along the Y2 line of FIG. 1B, according to embodiments.

FIG. 1B is a top view of the semiconductor device of FIGS. 1A, according to embodiments.

FIG. 2 is a cross-sectional view of the semiconductor device of FIG. 1A after additional fabrication operations and taken along the Y2 line of FIG. 1B, according to embodiments.

FIG. 3 is a cross-sectional view of the semiconductor device of FIG. 2 after additional fabrication operations and taken along the Y2 line of FIG. 1B, according to embodiments.

FIG. 4 is a cross-sectional view of the semiconductor device of FIG. 3 after additional fabrication operations and taken along the Y2 line of FIG. 1B, according to embodiments.

FIG. 5A is a cross-sectional view of the semiconductor device of FIG. 4 after additional fabrication operations and taken along the Y1 line of FIG. 1B, according to embodiments.

FIG. 5B is a cross-sectional view of the semiconductor device of FIG. 4 after additional fabrication operations and taken along the Y2 line of FIG. 1B, according to embodiments.

FIG. 5C is a cross-sectional view of the semiconductor device of FIG. 4 after additional fabrication operations and taken along the X line of FIG. 1B, according to embodiments.

FIG. 6A is a cross-sectional view of the semiconductor device of FIG. 5A after additional fabrication operations and taken along the Y1 line of FIG. 1B, according to embodiments.

FIG. 6B is a cross-sectional view of the semiconductor device of FIG. 5B after additional fabrication operations and taken along the Y2 line of FIG. 1B, according to embodiments.

FIG. 6C is a cross-sectional view of the semiconductor device of FIG. 5C after additional fabrication operations and taken along the X line of FIG. 1B, according to embodiments.

FIG. 7A is a cross-sectional view of the semiconductor device of FIG. 6A after embodiments.

FIG. 7B is a cross-sectional view of the semiconductor device of FIG. 6B after additional fabrication operations and taken along the Y2 line of FIG. 1B, according to embodiments.

FIG. 7C is a cross-sectional view of the semiconductor device of FIG. 6C after additional fabrication operations and taken along the X line of FIG. 1B, according to embodiments.

FIG. 8A is a cross-sectional view of the semiconductor device of FIG. 7A after additional fabrication operations and taken along the Y1 line of FIG. 1B, according to embodiments.

FIG. 8B is a cross-sectional view of the semiconductor device of FIG. 7B after additional fabrication operations and taken along the Y2 line of FIG. 1B, according to embodiments.

FIG. 8C is a cross-sectional view of the semiconductor device of FIG. 7C after additional fabrication operations and taken along the X line of FIG. 1B, according to embodiments.

FIG. 9A is a cross-sectional view of the semiconductor device of FIG. 8A after additional fabrication operations and taken along the Y1 line of FIG. 1B, according to embodiments.

FIG. 9B is a cross-sectional view of the semiconductor device of FIG. 8B after additional fabrication operations and taken along the Y2 line of FIG. 1B, according to embodiments.

FIG. 9C is a cross-sectional view of the semiconductor device of FIG. 8C after additional fabrication operations and taken along the X line of FIG. 1B, according to embodiments.

FIG. 10A is a cross-sectional view of the semiconductor device of FIG. 9A after embodiments.

FIG. 10B is a cross-sectional view of the semiconductor device of FIG. 9B after additional fabrication operations and taken along the Y2 line of FIG. 1B, according to embodiments.

FIG. 10C is a cross-sectional view of the semiconductor device of FIG. 9C after additional fabrication operations and taken along the X line of FIG. 1B, according to embodiments.

FIG. 11A is a cross-sectional view of the semiconductor device of FIG. 10A after additional fabrication operations and taken along the Y1 line of FIG. 1B, according to embodiments.

FIG. 11B is a cross-sectional view of the semiconductor device of FIG. 10B after additional fabrication operations and taken along the Y2 line of FIG. 1B, according to embodiments.

FIG. 11C is a cross-sectional view of the semiconductor device of FIG. 10C after additional fabrication operations and taken along the X line of FIG. 1B, according to embodiments.

FIG. 12A is a cross-sectional view of the semiconductor device of FIG. 11A after additional fabrication operations and taken along the Y1 line of FIG. 1B, according to embodiments.

FIG. 12B is a cross-sectional view of the semiconductor device of FIG. 11B after additional fabrication operations and taken along the Y2 line of FIG. 1B, according to embodiments.

FIG. 12C is a cross-sectional view of the semiconductor device of FIG. 11C after additional fabrication operations and taken along the X line of FIG. 1B, according to embodiments.

FIG. 13A is a cross-sectional view of the semiconductor device of FIG. 12A after embodiments.

FIG. 13B is a cross-sectional view of the semiconductor device of FIG. 12B after additional fabrication operations and taken along the Y2 line of FIG. 1B, according to embodiments.

FIG. 13C is a cross-sectional view of the semiconductor device of FIG. 12C after additional fabrication operations and taken along the X line of FIG. 1B, according to embodiments.

FIG. 14A is a cross-sectional view of the semiconductor device of FIG. 13A after additional fabrication operations and taken along the Y1 line of FIG. 1B, according to embodiments.

FIG. 14B is a cross-sectional view of the semiconductor device of FIG. 13B after additional fabrication operations and taken along the Y2 line of FIG. 1B, according to embodiments.

FIG. 14C is a cross-sectional view of the semiconductor device of FIG. 13C after additional fabrication operations and taken along the X line of FIG. 1B, according to embodiments.

FIG. 15A is a cross-sectional view of the semiconductor device of FIG. 14A after additional fabrication operations and taken along the Y1 line of FIG. 1B, according to embodiments.

FIG. 15B is a cross-sectional view of the semiconductor device of FIG. 14B after additional fabrication operations and taken along the Y2 line of FIG. 1B, according to embodiments.

FIG. 15C is a cross-sectional view of the semiconductor device of FIG. 14C after additional fabrication operations and taken along the X line of FIG. 1B, according to embodiments.

FIG. 16A is a cross-sectional view of the semiconductor device of FIG. 15A after embodiments.

FIG. 16B is a cross-sectional view of the semiconductor device of FIG. 15B after additional fabrication operations and taken along the Y2 line of FIG. 1B, according to embodiments.

FIG. 16C is a cross-sectional view of the semiconductor device of FIG. 15C after additional fabrication operations and taken along the X line of FIG. 1B, according to embodiments.

### DETAILED DESCRIPTION

The present disclosure describes stacked FET devices and methods of manufacturing the stacked FET devices. In particular, the present disclosure describes staircase stacked nanosheet FET devices and the particular contact wiring structures formed therein. In general, a staircase structure refers to the idea that a bottom FET has a different sized footprint (i.e., as seen in a top-down or plan view) than that of the top FET. This allows contacts to formed to connect to the bottom FET without causing an electrical short to the source/drain epitaxial portion of the top FET.

In certain examples, forming staircase stacked FET devices may have certain challenges. forming staircase top and bottom active regions in early stage of the process flow may cause issues during gate formation, spacer formation and source/drain epitaxy formation. Therefore, it may be desirable to manufacture staircase stacked nanosheet FET structures by first defining the size of the top active area (RX) in the first hardmask, and defining the size of the bottom RX in first and second hardmask. Then, patterning may be performed on the stacked FET nanosheet stack so that the top RX and the bottom RX have the same size. Then, the dummy gate, inner spacer, and source/drain (S/D) epitaxial regions may be formed without any issues. Then, partially recessing the dummy gate to reveal the first and second hardmask may be performed. Then, selectively removing the second hardmask may be performed. The, the top RX may be cut so that the top RX has a smaller size than bottom RX.

The flowcharts and cross-sectional diagrams in the Figures illustrate methods of manufacturing nanosheet FET devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

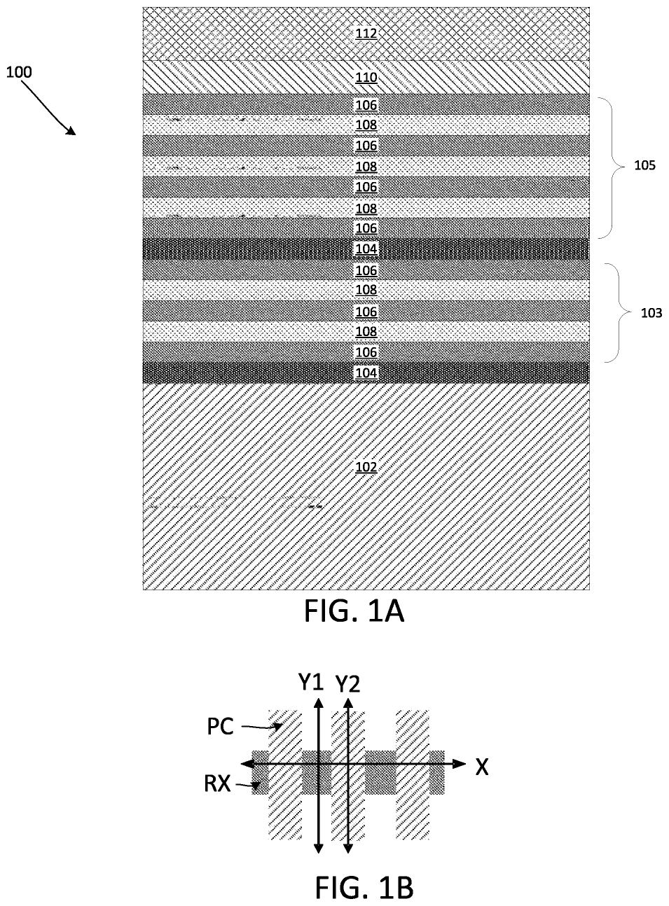

Referring now to the drawings in which like numerals represent the same or similar elements and initially to FIG. 1A, this figure depicts a cross-sectional view of the semiconductor device 100 shown in FIG. 1B taken along line Y2, according to embodiments. FIG. 1B is a simplified top-down (or plan) view of the semiconductor device 100 to show the various cut lines, the active area (RX) and the location of the gate cuts. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

As shown in FIG. 1A, a first sacrificial epitaxial layer 104 is formed on the underlying substrate 102. The first sacrificial epitaxial layer 104 may be comprised of, for example, SiGe with Ge concentration ranging from 50% to 75% (e.g., SiGe55), or any other suitable material. As discussed in further detail below, the first sacrificial epitaxial layer 104 is later selectively removed and replaced by a dielectric material during downstream processing to create a continuous isolation layer under the source-drain and gate regions of active FET devices.

As shown in FIGS. 1A, a bottom multi-layer nanosheet stack 103 is formed on first type sacrificial epitaxial layer 104. The nanosheet stack 103 includes a second type sacrificial layer 106, followed by the formation of an active semiconductor layer 108. In certain examples, the first one of the second type sacrificial layers 108 (i.e., the bottommost second type sacrificial layer) is initially formed directly on an upper surface of first sacrificial epitaxial layer 104. In other examples, certain layers may be formed between the upper surface of the first type sacrificial epitaxial layer 104 and the first one of the second type sacrificial layers 106. In an example, the second type sacrificial layer 106 is composed of silicon-germanium (e.g., SiGe35, or more generally, where the Ge ranges from about 15-35%). Thus, the germanium content of the second type sacrificial layer 106 is different from the germanium content of the first type sacrificial layer 104 to allow for selective etching in downstream process flows. Next, an active semiconductor layer 108 is formed on an upper surface of the first one of the second type sacrificial layers 106. In an example, the active semiconductor layer 108 is composed of silicon. Several additional layers of the second type sacrificial layer 106 and the active semiconductor layer 108 are alternately formed. In the example illustrated in FIG. 1A, there are a total of three second type sacrificial layers 106 and two active semiconductor layers 108 that are alternately formed to form the bottom nanosheet stack 103. However, it should be appreciated that any suitable number of alternating layers may be formed. Then, as shown in FIG. 1A, another first type sacrificial layer 104 is formed on the bottom nanosheet stack 103. This first type sacrificial layer 104 (i.e., formed on the bottom nanosheet stack 103) may be comprised of the same or similar materials to the first type sacrificial layer 104 formed under the bottom nanosheet stack 103. In a process similar to that described above, a top nanosheet stack 105 is formed. In the example shown in FIG. 1A, a total of four second type sacrificial layers 106 and three active semiconductor layers 108 are formed in the top nanosheet stack 105. However, it should be appreciated that the total number of alternating layers in the top nanosheet stack 105 may be any suitable number.

In certain embodiments, the first type sacrificial layers 104 and the second type sacrificial layers have a vertical thickness ranging, for example, from approximately 3 nm to approximately 20 nm. In certain embodiments, the active semiconductor layers 108 have a vertical thickness ranging, for example, from approximately 3 nm to approximately 10 nm. Although the range of 3-20 nm is cited as an example range of thickness, other thicknesses of these layers may be used. In certain examples, certain of the first type sacrificial layers 104, the second type sacrificial layers 106, or the active semiconductor layers 108 may have different thicknesses relative to one another. Therefore, multiple epitaxial growth processes can be performed to form the first type sacrificial layers 104, the second type sacrificial layers 106, and the active semiconductor layers 108 shown in FIG. 1A.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 104. As also shown in FIG. 1A, a first hardmask 110 is formed on the upper surface of the top nanosheet stack 105. The first hardmask 110 may be comprised of, for example, SiO₂ or any other suitable material. Then, a nitride layer 112 (e.g., SiN) is formed on the first hardmask 110.

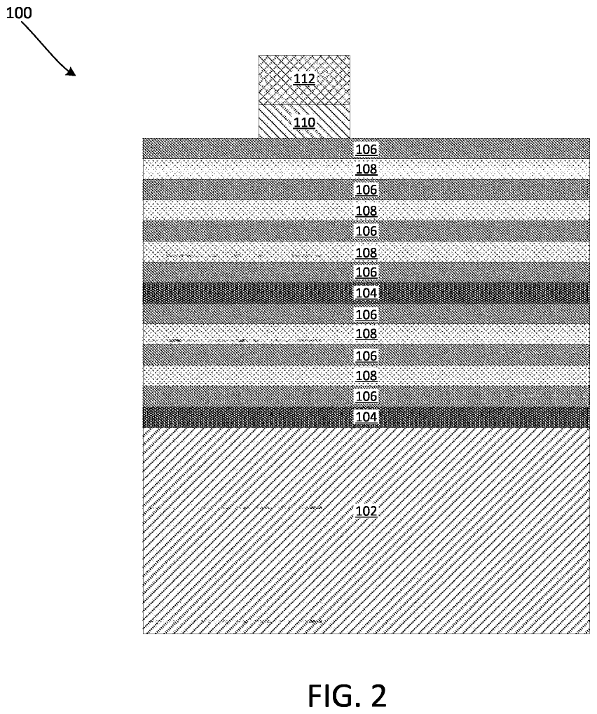

Referring now to FIG. 2, this figure depicts a cross-sectional view of the semiconductor device 100 shown in FIG. 1A taken along line Y2 after additional manufacturing operations, according to embodiments. As shown in FIG. 2, the first hardmask 110 and the nitride layer 112 are patterned and sized to correspond to what will later be the top active region (RX) of the top FET. Any suitable combination of deposition, lithography and material removal processed may be used to form and pattern the first hardmask 110 and nitride layer 112.

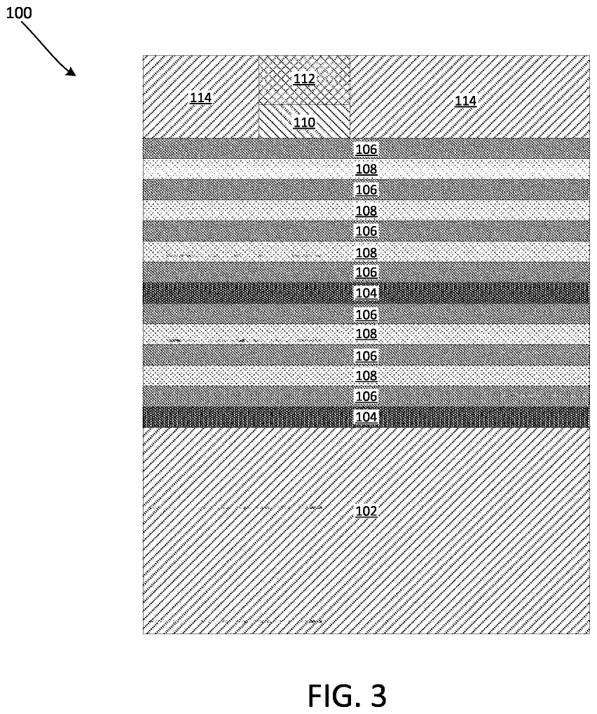

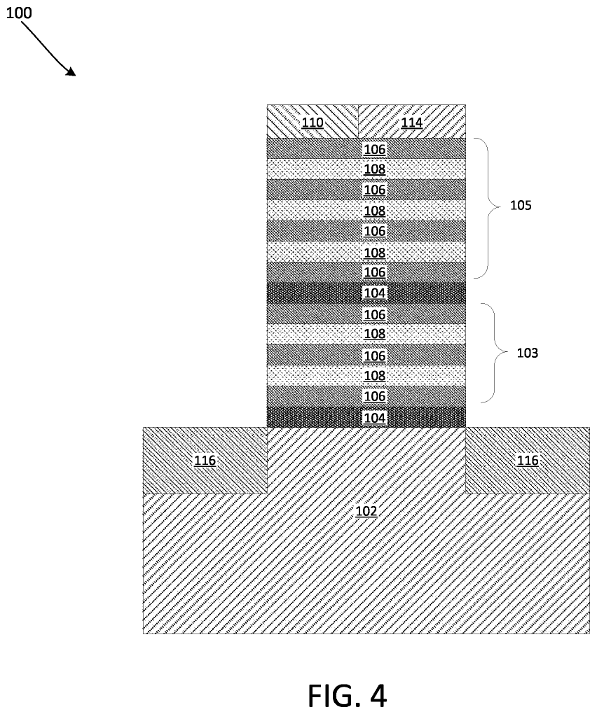

Referring now to FIG. 3, this figure depicts a cross-sectional view of the semiconductor device 100 shown in FIG. 2 taken along line Y2 after additional manufacturing operations, according to embodiments. As shown in FIG. 3, a second hardmask 114 is formed. The second hardmask 114 may comprise, for example, SiC or SiCO. In certain embodiments, the material of the second hardmask 114 is different from the material of the first hardmask 110. A planarization technique such as CMP may be performed on the top surface of the semiconductor device 100 after deposition of the second hardmask 114 to remove any overburden.

Referring now to FIG. 4, this figure depicts a cross-sectional view of the semiconductor device 100 shown in FIG. 3 taken along line Y2 after additional manufacturing operations, according to embodiments. As shown in FIG. 4, the semiconductor device 100 is patterned to create the nanosheet stack. The SiN layer 112 is removed and the second hardmask 114 is thinned so that the top surface of the first hardmask 110 is coplanar with the top surface of the second hardmask 114. As mentioned above, the first hardmask 110 generally defines the area of the first active area of the top FET 105, and the combination of the first hardmask 110 and the second hardmask 114 helps define the shape of the second active area of the bottom FET 103. However, at this stage there is no staircase structure (i.e., where the top FET 105 has a smaller footprint than the bottom FET 103) formed due to the existence of the second hardmask 114. As mentioned above, once the staircase structure is formed it may present difficulties with subsequent manufacturing operations. As shown in FIG. 4, the etching is performed so as to remove a portion of the substrate 102 adjacent to the fin, and shallow trench isolation (STI) regions are formed in these etched out areas. In general, shallow trench isolation is an integrated circuit feature which prevents electric current leakage between adjacent semiconductor device components. STI is generally used on CMOS process technology nodes of 250 nanometers and smaller. STI is created early during the semiconductor device fabrication process, before transistors are formed. The key steps of the STI process involve etching a pattern of trenches in the silicon, depositing one or more dielectric materials (such as silicon dioxide) to fill the trenches, and removing the excess dielectric using a technique such as chemical-mechanical planarization.

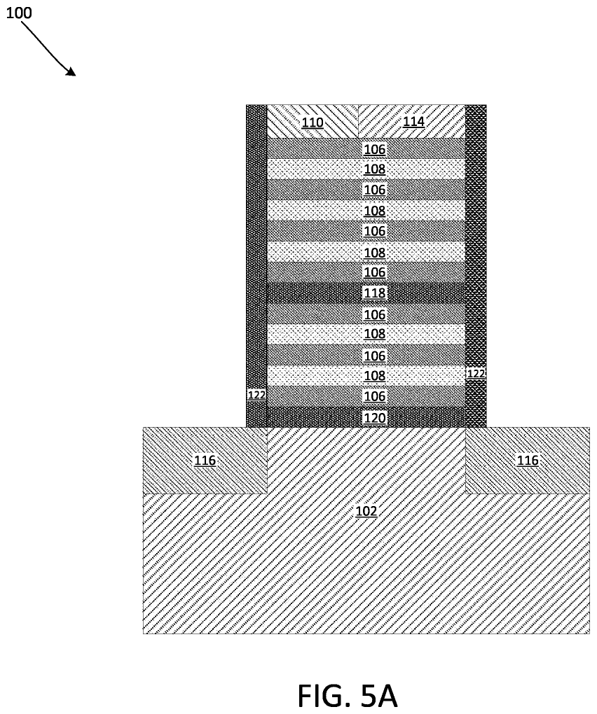

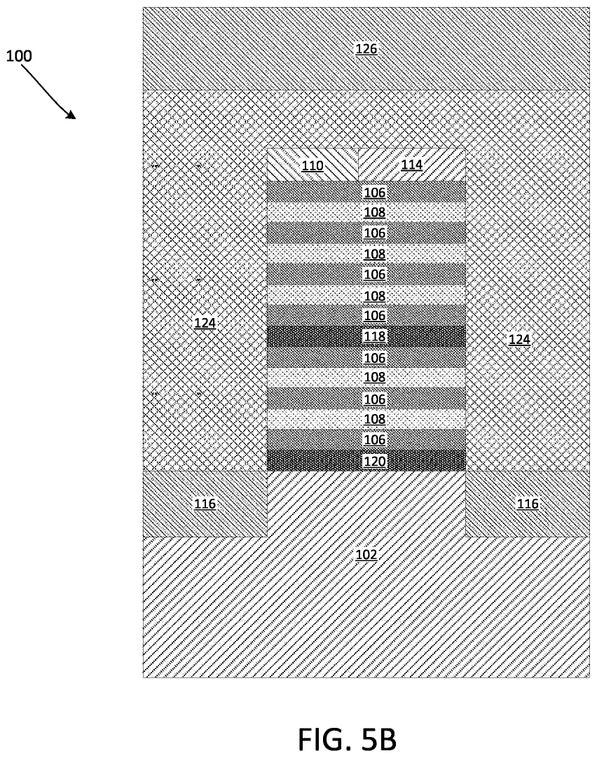

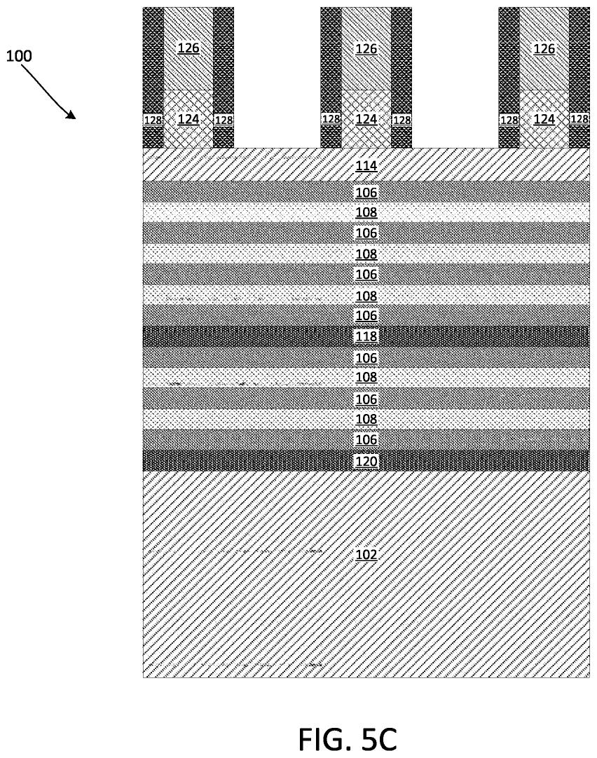

FIGS. 5A, 5B and 5C illustrate the process stage after formation of dummy gate removing the sacrificial layers 104, forming gate spacers 128 and dielectric solation layers 118/120. Referring now to FIG. 5B, this figure depicts a cross-sectional view of the semiconductor device 100 shown in FIG. 4 taken along line Y2 of FIG. 1B, after additional manufacturing operations, according to embodiments. As shown in FIG. 5B and FIG. 5C (a cross-sectional view of the semiconductor device 100 shown in FIG. 4 taken along line X of FIG. 1B), a dummy gate 124 is formed. The dummy gate 124 may be formed by any suitable deposition technique known to one of skill in the art. In one example, the dummy gate 124 is formed by depositing a thin SiO₂ dummy gate oxide layer (not shown), followed by depositing a layer of amorphous silicon (a-Si) as the dummy gate 124. The dummy gate 124 may be composed of polycrystalline silicon (poly silicon), amorphous silicon, and/or an oxide, such as, SiO₂. In certain examples, gate patterning may be performed by first patterning a gate hardmask 126 and then using the patterned gate hardmask to etch the dummy gates 124. After the dummy gate 124 is formed, as shown in FIG. 1A, the first type sacrificial layers 104 are removed by any suitable material removal process knows to one of skill in the art. Then, a spacer material is conformally deposited over the dummy gates 124 and in the areas between where the first type sacrificial layers 104 were removed and the active semiconductor layers 108. In certain embodiments, the material of the spacer forms a bottom dielectric isolation layer 120, a middle dielectric isolation layer 118, side dielectric isolation layers 122 (as shown in FIG. 5A which is a cross-sectional view of the semiconductor device 100 shown in FIG. 4 taken along line Y1 of FIG. 1B), and gate spacer 128 as shown in FIG. 5C. Note that all of these different dielectric isolation layers may be deposited in a single conformal deposition step followed by an anisotropic etch process, so some of the layers may be continuous (e.g., the bottom dielectric isolation layer 120, the middle dielectric isolation layer 118, and the side dielectric isolation layers 122). Therefore, as can be seen from FIGS. 5A-5C these dielectric spacer layers (or isolation layers) are formed before the staircase structure of the top and bottom FETs is formed.

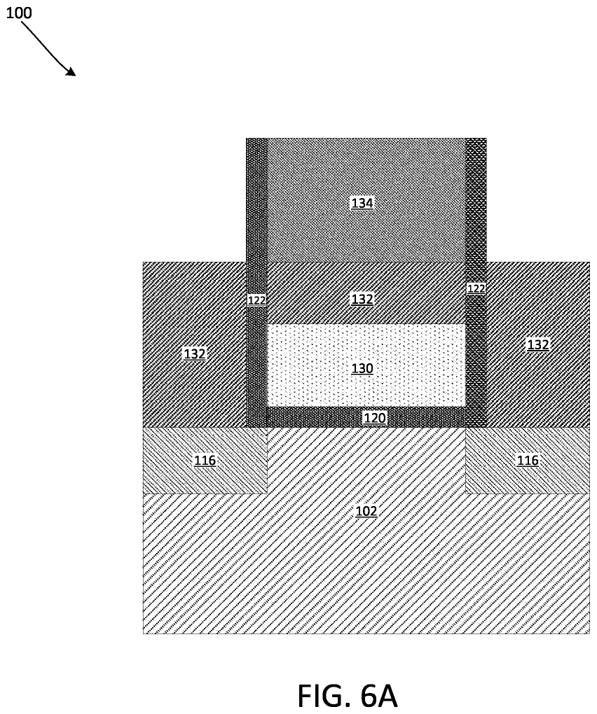

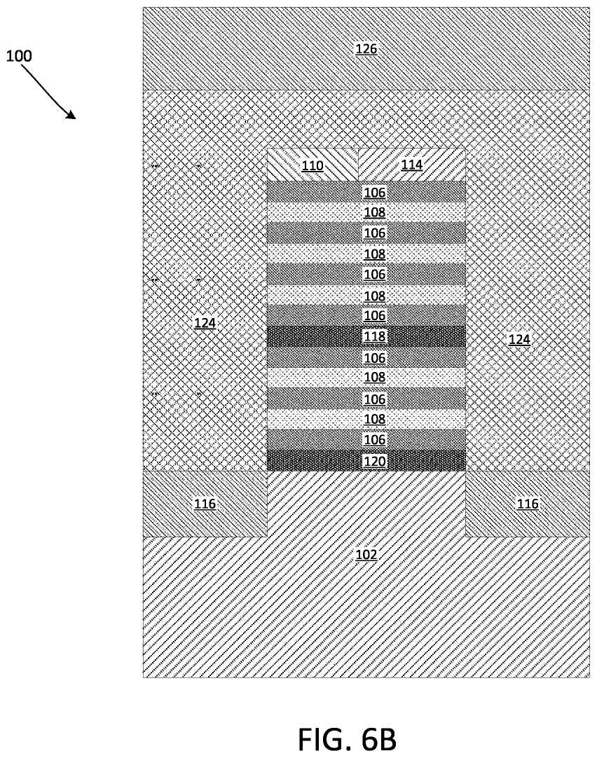

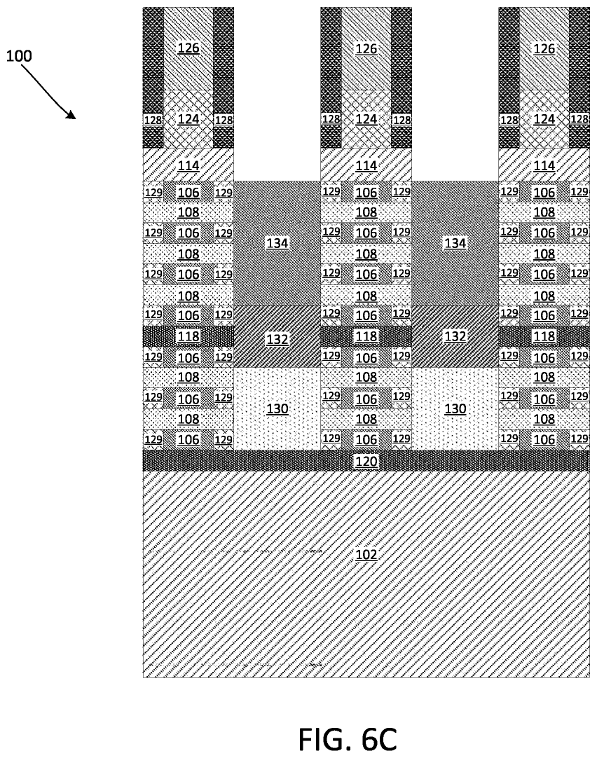

FIGS. 6A, 6B and 6C illustrate a process stage after stacked nanosheets are recessed, followed by inner spacer 129 formation, bottom S/D epi 130 formation, bottom ILD 132 deposition, and top source/drain epi 134 formation. Referring now to FIG. 6C, this figure depicts a cross-sectional view of the semiconductor device 100 shown in FIG. 5C taken along line X of FIG. 1B, after additional manufacturing operations, according to embodiments. As shown in FIG. 6C, an etching process is performed to recess the nanosheet stack. The fin etching process is followed by a selective etching process, which is capable of removing portions of the second type sacrificial layers 106. The selective etching process can use a boron-based chemistry or a chlorine-based chemistry, for example, which selectively recesses the exposed portions second type sacrificial layers 106 without significantly attacking the surrounding materials. Then, inner spacers 129 are formed in the indents created by the removal of the portions of the second type sacrificial layers 106. An isotropic etching process may be performed to clean up the edges of the inner spacers 129. There are no changes between FIG. 6B and FIG. 5B. Then, as shown in FIGS. 6C and 6A (a cross-sectional view of the semiconductor device 100 shown in FIG. 5A taken along line Y1 of FIG. 1B, after additional manufacturing operations), a bottom source/drain epitaxial layer 130 is formed on the bottom dielectric isolation layer 120 and around the nanosheet stacks 103 and 105. Then, a bottom interlayer dielectric (ILD) layer 132 is formed on the bottom epitaxial layer 130 as shown in FIGS. 6A and 6C. Then, a top source/drain epitaxial layer 134 is formed on the ILD layer 132.

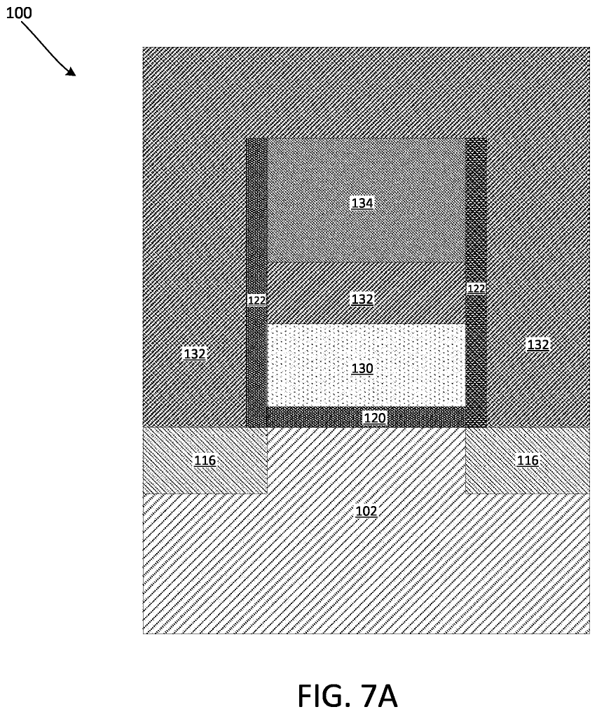

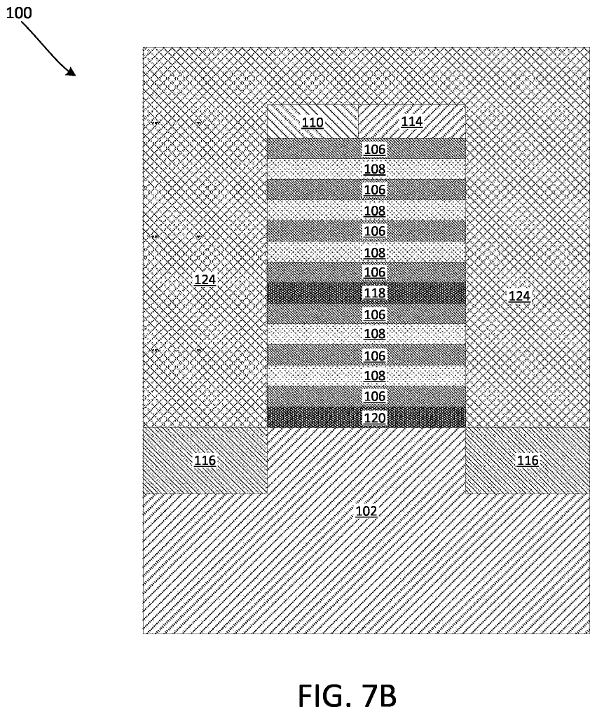

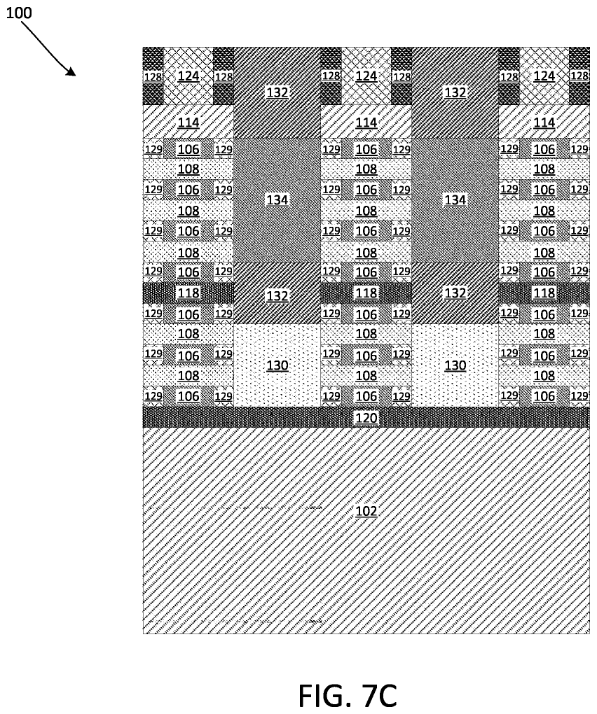

FIGS. 7A, 7B and 7C illustrate a process stage after depositing top ILD 132 followed by CMP process. Referring now to FIG. 7C, this figure depicts a cross-sectional view of the semiconductor device 100 shown in FIG. 6C taken along line X of FIG. 1B, after additional manufacturing operations, according to embodiments. As shown in FIGS. 7A and 7C, additional dielectric material is deposited to extend the ILD layer 132 up to the level of a top surface of the dummy gate 124. It should be appreciated that this additional ILD material of the ILD layer 132 may be the same as or different than the material used to form the first part of the ILD layer 132. A planarization technique such as CMP may be performed on the top surface of the semiconductor device 100 after deposition of the additional ILD layer 132 material to remove any overburden. FIG. 7B shows the removal of the hardmask 126.

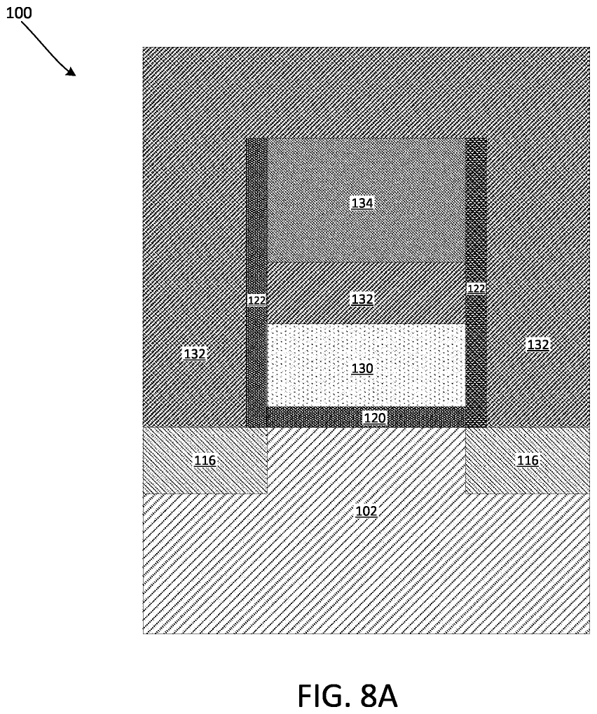

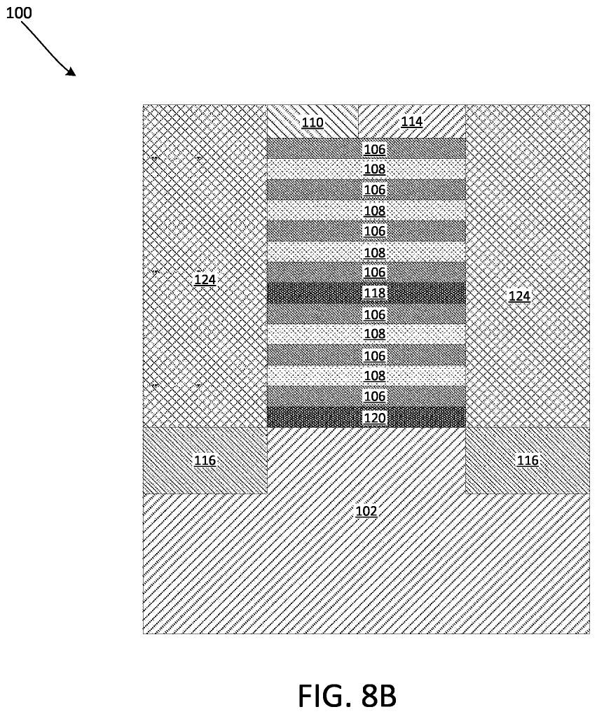

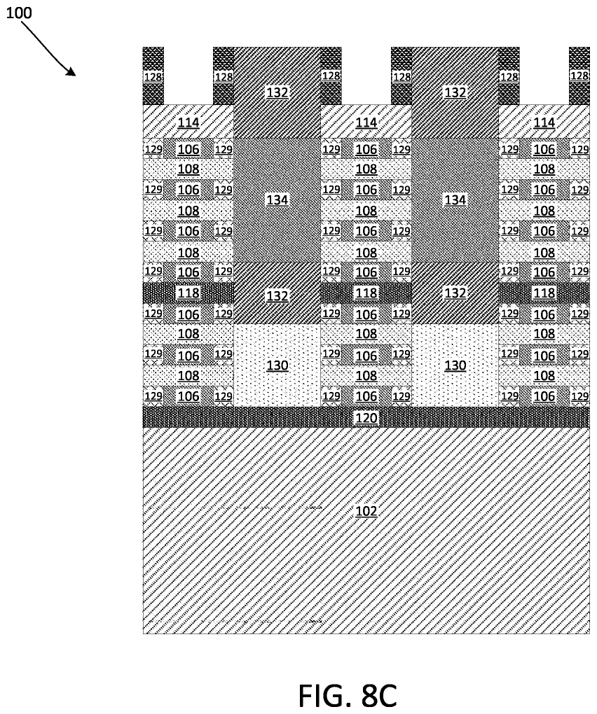

FIGS. 8A, 8B and 8C illustrate a process stage after partial dummy gate recess such that hardmask 110 and 114 are revealed. Referring now to FIG. 8C, this figure depicts a cross-sectional view of the semiconductor device 100 shown in FIG. 7C taken along line X of FIG. 1B, after additional manufacturing operations, according to embodiments. There are no changes between FIG. 8A and FIG. 7A. As shown in FIGS. 8C and 8B (a cross-sectional view of the semiconductor device 100 shown in FIG. 7B taken along line Y2 of FIG. 1B, after additional manufacturing operations), a partial gate recess operation is performed to lower the level of the dummy gate 124 down to a level that is at or below an upper surface of the second hardmask 114. As such, the second hardmask 114 is now exposed as shown in FIG. 8C.

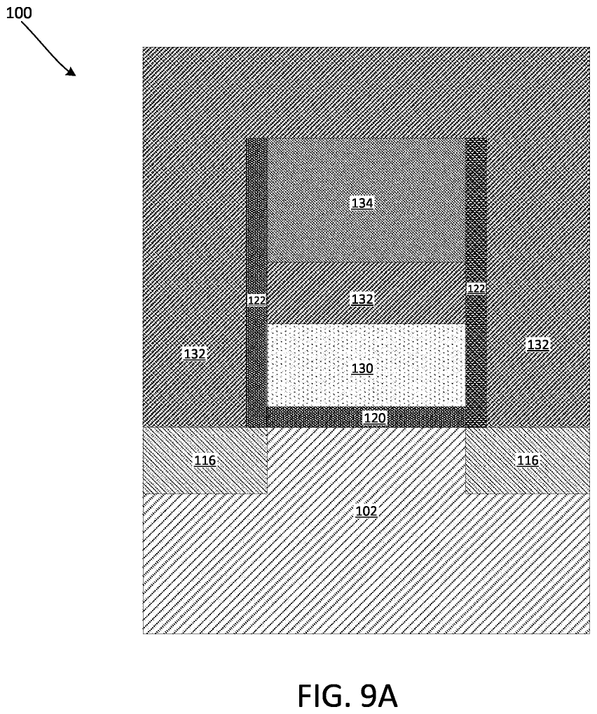

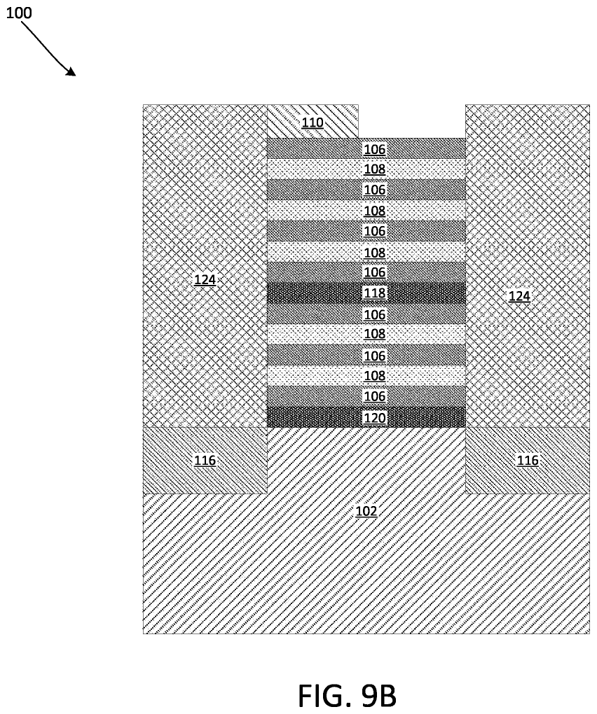

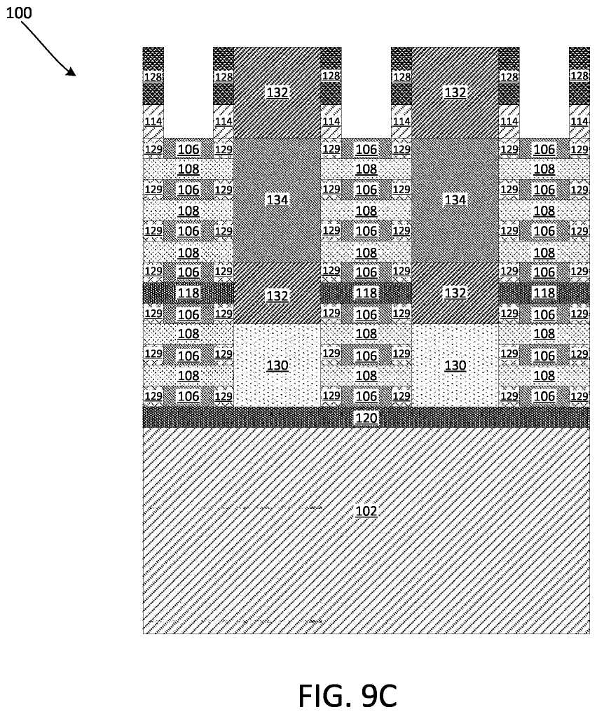

FIGS. 9A, 9B and 9C illustrate a process stage after second hardmask 114 exposed are selectively removed. Referring now to FIG. 9C, this figure depicts a cross-sectional view of the semiconductor device 100 shown in FIG. 8C taken along line X of FIG. 1B, after additional manufacturing operations, according to embodiments. There are no changes between FIG. 9A and FIG. 8A. As shown in FIGS. 9C and 9B (a cross-sectional view of the semiconductor device 100 shown in FIG. 8B taken along line Y2 of FIG. 1B, after additional manufacturing operations), a material removal process is performed to selectively remove the second hardmask 114. Thus, the nanosheet stack is now ready to perform the top channel cut.

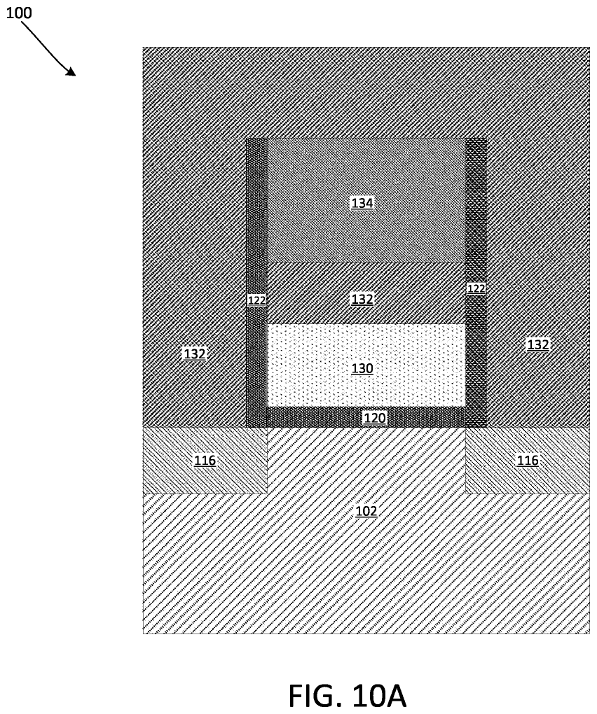

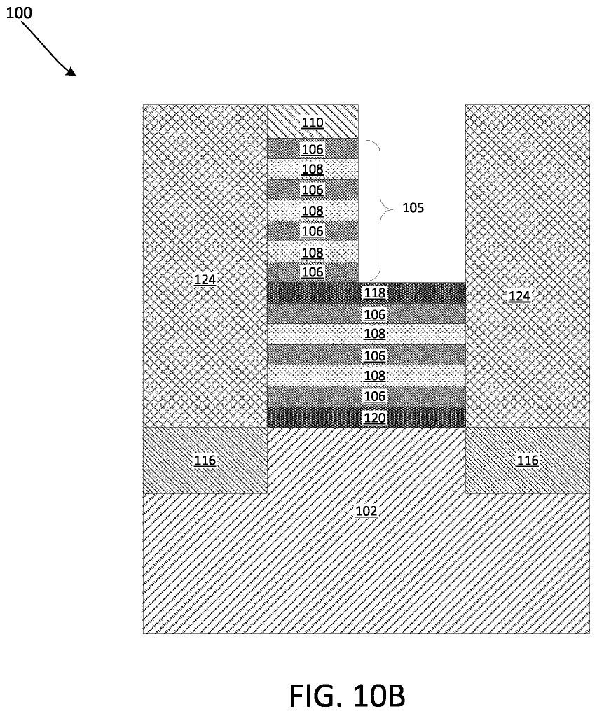

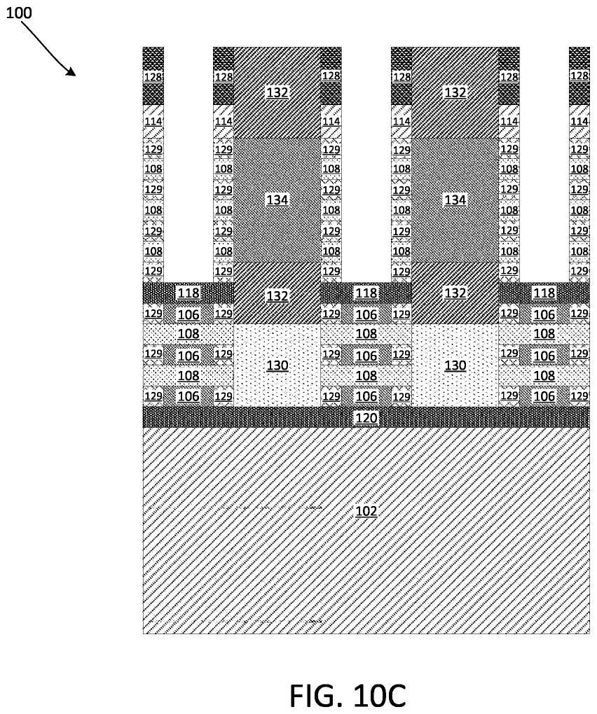

FIGS. 10A, 10B and 10C illustrate the process stage after top channel cut. Referring now to FIG. 10C, this figure depicts a cross-sectional view of the semiconductor device 100 shown in FIG. 9C taken along line X of FIG. 1B, after additional manufacturing operations, according to embodiments. There are no changes between FIG. 10A and FIG. 9A. As shown in FIGS. 10C and 10B (a cross-sectional view of the semiconductor device 100 shown in FIG. 9B taken along line Y2 of FIG. 1B, after additional manufacturing operations), a suitable material removal process is used to perform the top channel cut, using the first hardmask 110 as a mask. In particular, as shown in FIG. 10B, the second type sacrificial layers 106 and the active semiconductor layers 108 of the top FET 105 are removed down to the level of the middle dielectric isolation layer 118 in the area not covered by the first hardmask 110. Thus, this material removal process reduces the footprint (or active area RX) of the top FET 105. As such, the staircase structure of the semiconductor device 100 is finally formed. That is, the active region of the top FET is laterally offset from an active region of the bottom FET 105. However, as mentioned above, the staircase structure is formed after the formation of gate spacer 128, S/D spacer 122, inner spacers 129, and therefore the manufacturing process may be improved or simplified. In FIG. 10, portions of the second hardmask 114 remain, even after the top channel cut is performed as shown in FIG. 10C.

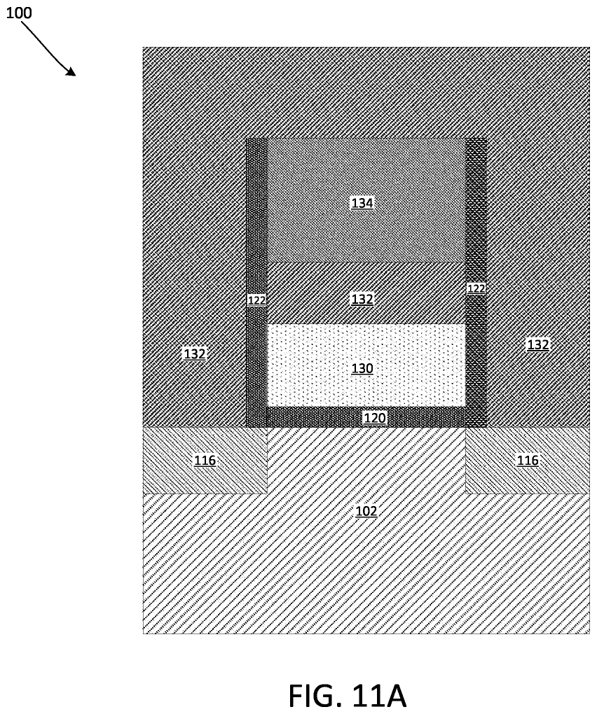

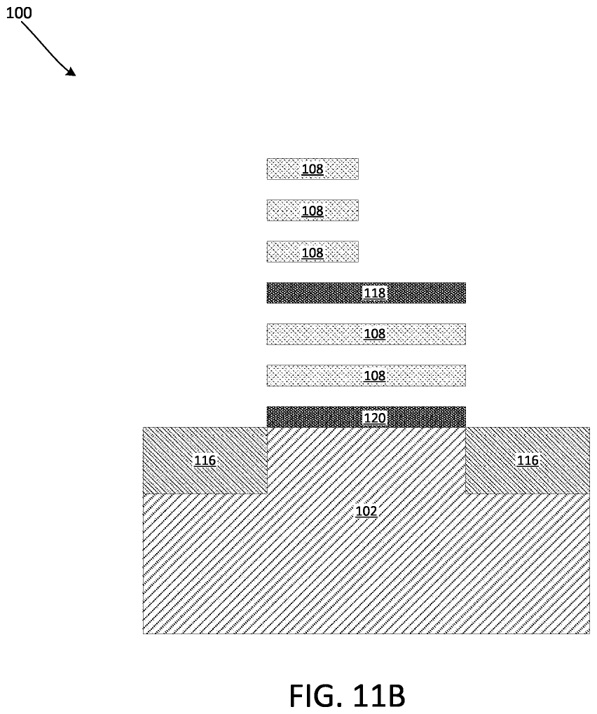

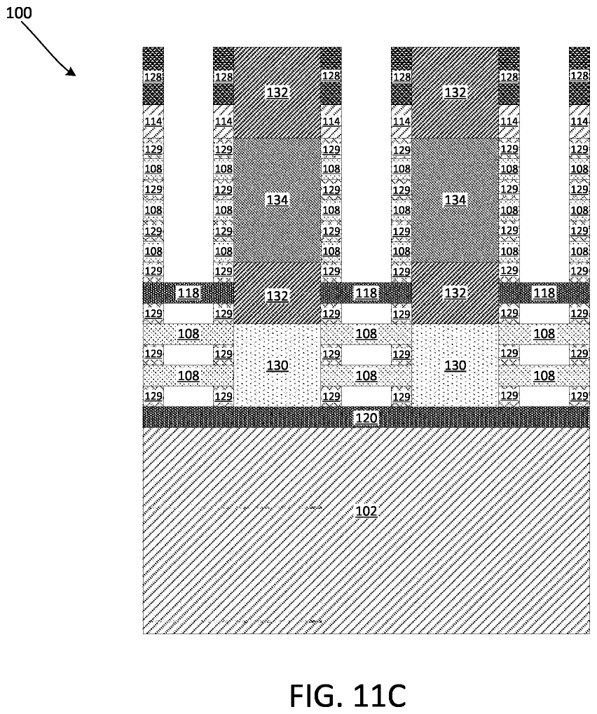

FIGS. 11A, 11B and 11C illustrate the process stage after dummy gate and sacrificial SiGe are removed. Referring now to FIG. 11C, this figure depicts a cross-sectional view of the semiconductor device 100 shown in FIG. 10C taken along line X of FIG. 1B, after additional manufacturing operations, according to embodiments. There are no changes between FIG. 11A and FIG. 10A. As shown in FIGS. 11C and 11B (a cross-sectional view of the semiconductor device 100 shown in FIG. 10B taken along line Y2 of FIG. 1B, after additional manufacturing operations), one or more suitable material removal processes are performed to remove the first hardmask 110, the dummy gate 124 and the SiGe material of the second type sacrificial layer 106.

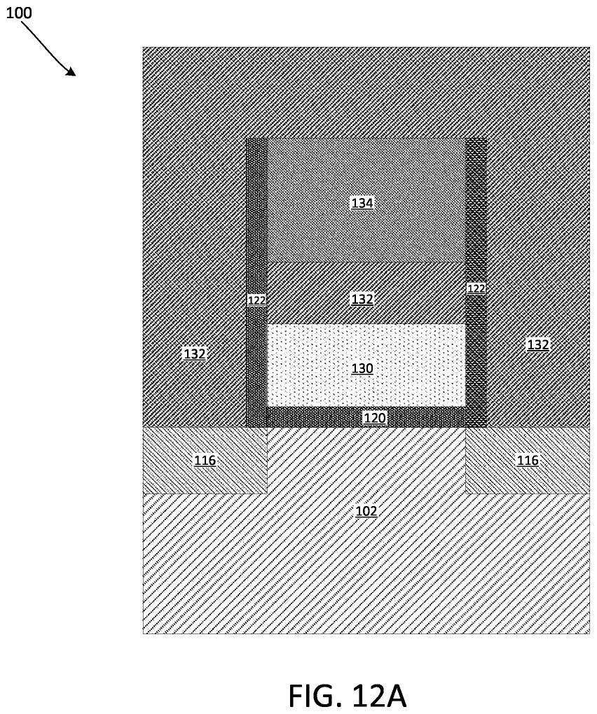

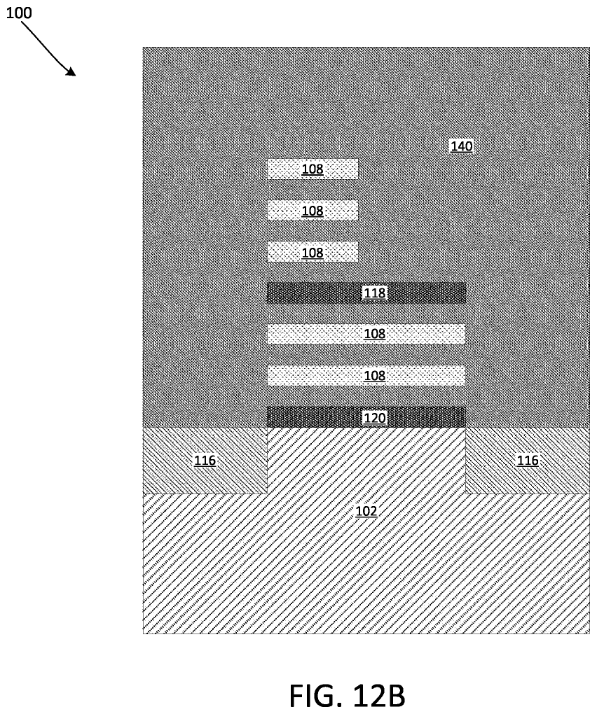

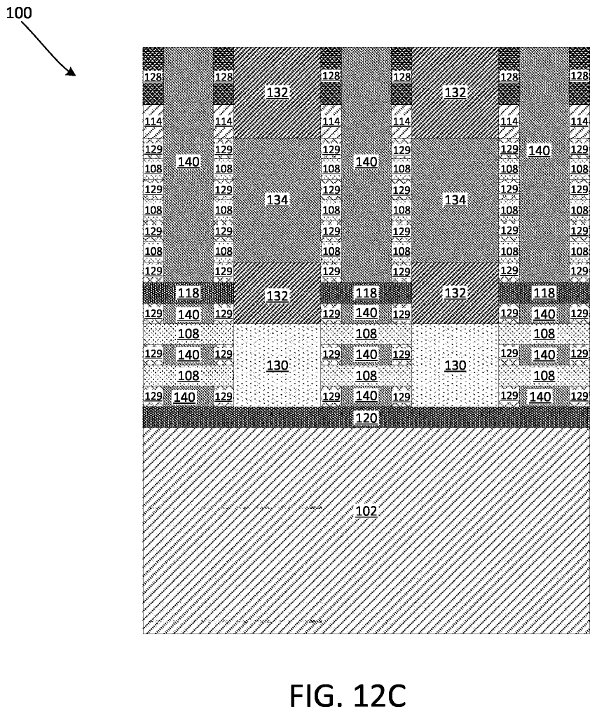

FIGS. 12A, 12B and 12C illustrate the process stage after formation of replacement gate 140. Referring now to FIG. 12C, this figure depicts a cross-sectional view of the semiconductor device 100 shown in FIG. 11C taken along line X of FIG. 1B, after additional manufacturing operations, according to embodiments. There are no changes between FIG. 12A and FIG. 11A. As shown in FIGS. 12C and 12B (a cross-sectional view of the semiconductor device 100 shown in FIG. 11B taken along line Y2 of FIG. 1B, after additional manufacturing operations), a high-κ metal gate (HKMG) 140 is formed in the spaces created by the removal of the first hardmask 110, the dummy gate 124 and the SiGe material of the second type sacrificial layer 106.

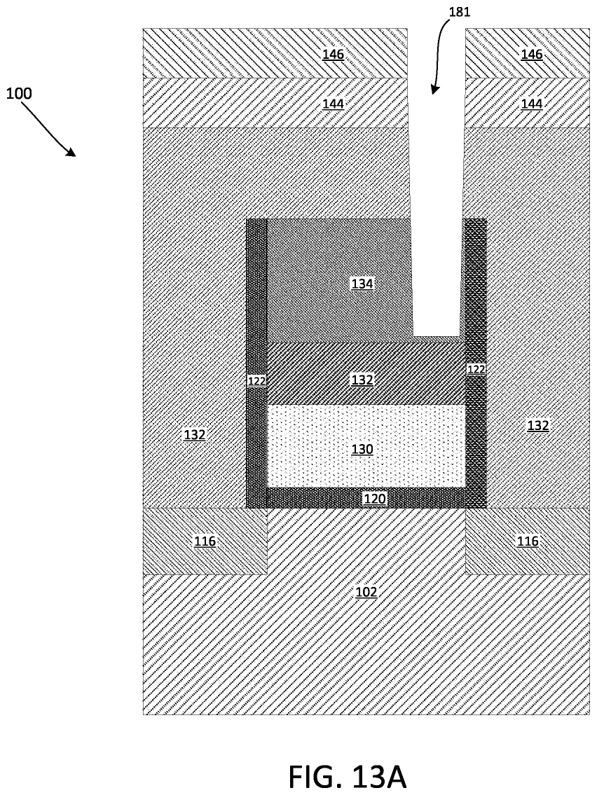

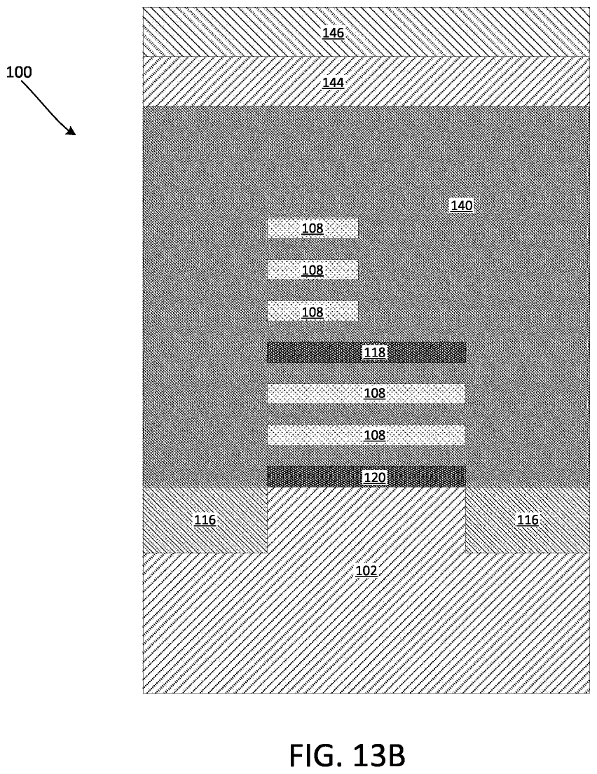

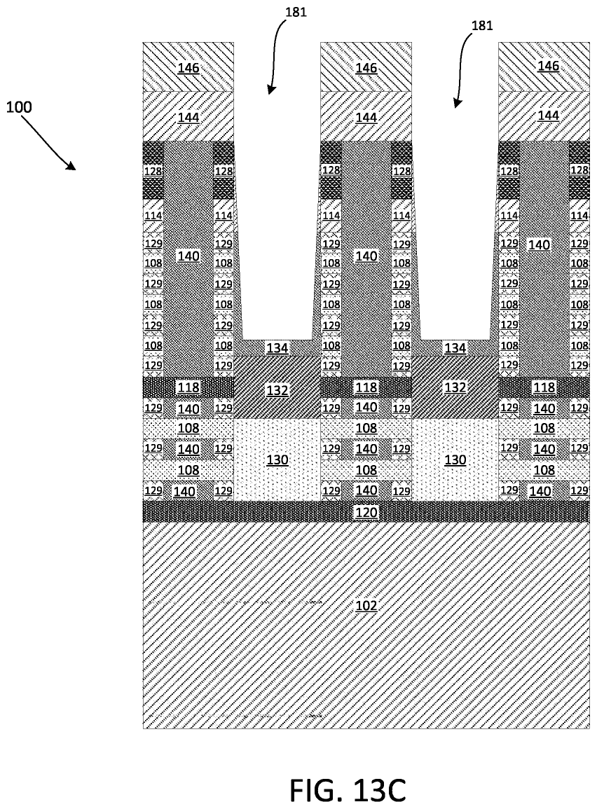

FIGS. 13A, 13B and 13C illustrate a process stage after forming the bottom source/drain contact via 181. Referring now to FIG. 13C, this figure depicts a cross-sectional view of the semiconductor device 100 shown in FIG. 12C taken along line X of FIG. 1B, after additional manufacturing operations, according to embodiments. As shown in FIGS. 13C, 13B (a cross-sectional view of the semiconductor device 100 shown in FIG. 11B taken along line Y2 of FIG. 1B, after additional manufacturing operations), and 13A (a cross-sectional view of the semiconductor device 100 shown in FIG. 12A taken along line Y1 of FIG. 1B, after additional manufacturing operations), additional dielectric material is deposited to further extend the ILD layer 132 up to the level that is above the top surface of the HKMG 140. It should be appreciated that this additional ILD material of the ILD layer 132 may be the same as or different than the material used to form the first and second parts of the ILD layer 132. A planarization technique such as CMP may be performed on the top surface of the semiconductor device 100 after deposition of the additional ILD layer 132 material to remove any overburden. Then, as shown in FIGS. 13A-13C, a third hardmask 146 (or patterning mask) is formed on the top surface of the ILD layer 132. Then, an etching process (or other suitable material removal process) is performed to create bottom contact vias 181. In certain examples, as shown in FIGS. 13A and 13C, the bottom contact vias 181 are not formed completely to the bottom of the top epitaxial layer 134.

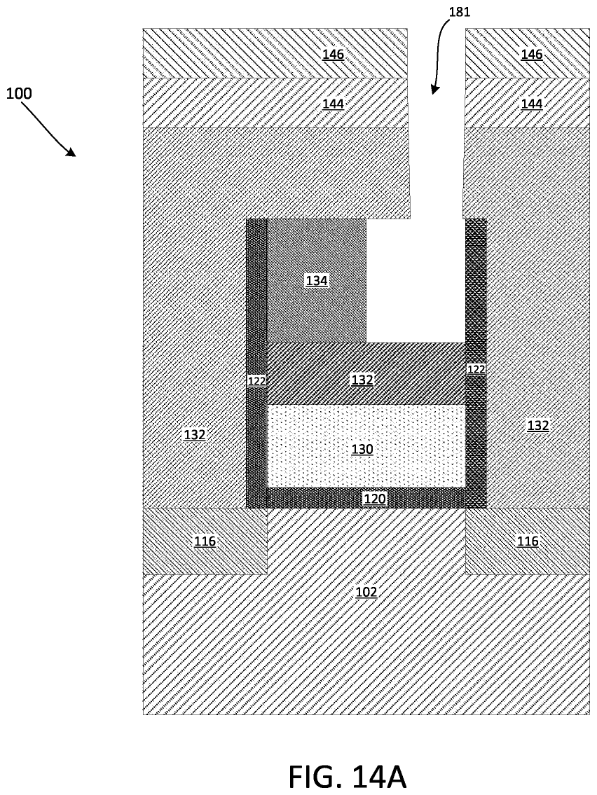

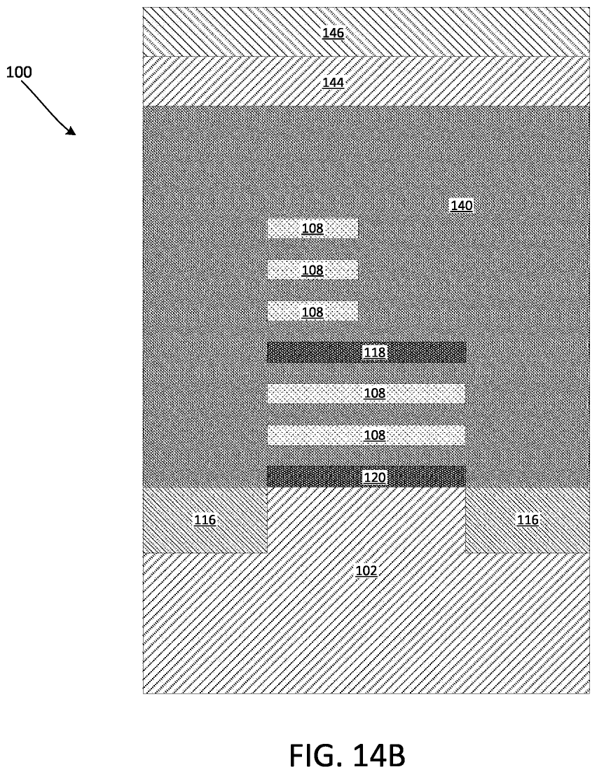

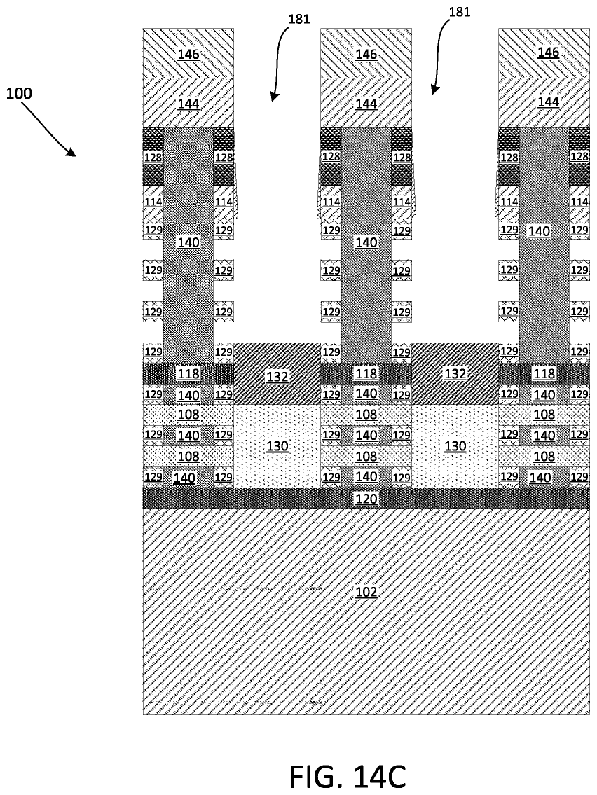

FIGS. 14A, 14B and 14C illustrate a process stage after lateral etching of semiconductor material (including top S/D epi 134, top channel Si 108) next to the bottom contact via 181. Referring now to FIG. 14C, this figure depicts a cross-sectional view of the semiconductor device 100 shown in FIG. 13C taken along line X of FIG. 1B, after additional manufacturing operations, according to embodiments. There are no changes between FIG. 14B and FIG. 13B. As shown in FIGS. 14A and 14C (a cross-sectional view of the semiconductor device 100 shown in FIG. 13C taken along line X of FIG. 1B, after additional manufacturing operations), an isotropic semiconductor etch is performed to further remove material of the top epitaxial layer 134. In particular, as shown in FIG. 14A, the etching is performed to create an undercut on the top epitaxial layer 134. Also, as shown in FIG. 14C, the remaining material of the top epitaxial layer 134 and the silicon material of the active semiconductor layers 108 are removed from the top FET 105.

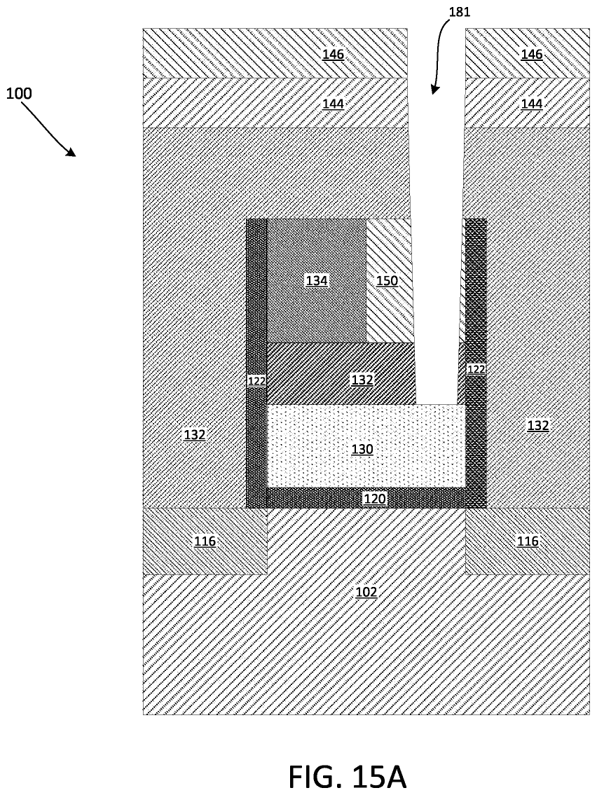

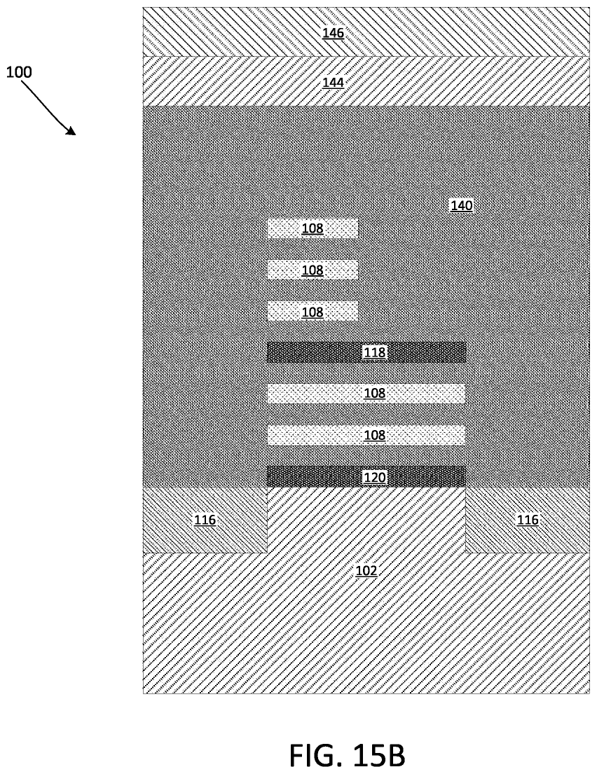

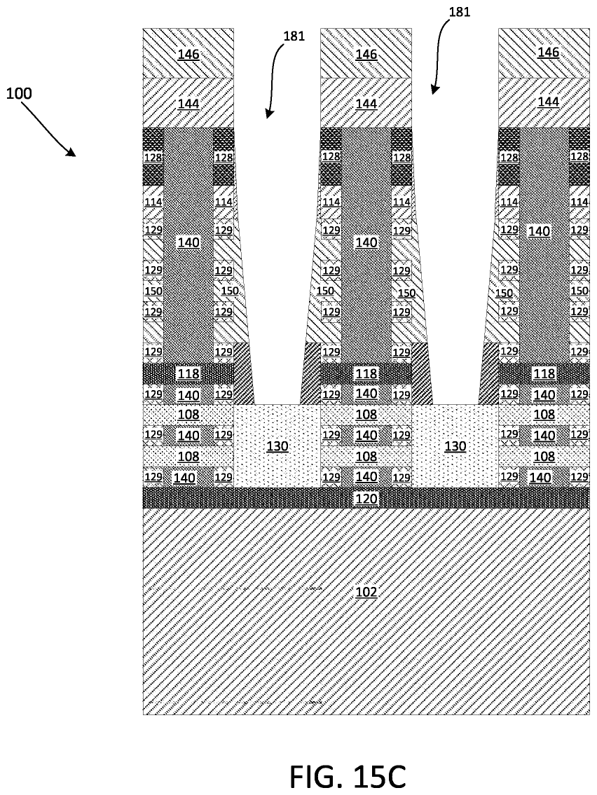

FIGS. 15A, 15B and 15C illustrate a process stage after forming a dielectric isolation layer 150 between top S/D epi 134 and bottom contact via 181 (also between gate 140 and bottom contact via 181). Referring now to FIG. 15C, this figure depicts a cross-sectional view of the semiconductor device 100 shown in FIG. 14C taken along line X of FIG. 1B, after additional manufacturing operations, according to embodiments. There are no changes between FIG. 15B and FIG. 15B. As shown in FIGS. 15A and 15C (a cross-sectional view of the semiconductor device 100 shown in FIG. 14C taken along line X of FIG. 1B, after additional manufacturing operations), a second dielectric layer 150 is first deposited to completely fill in the spaces that were etched away in the processes described above with respect to FIGS. 14A-14C (i.e., the indents where the Si material of the active semiconductor layers 108 of the top FET 105 and the top epitaxial layer 134). Although not seen in FIGS. 15A and 15C, this deposition of the second dielectric layer 150 may at least initially fill or almost fill the entire bottom contact vias 181. In a second step, the bottom contact vias 181 are reformed by another etching process to expose the bottom epitaxial layer 130. Referring back to FIGS. 13A and 13C, it shows that the bottom contact vias 181 were not formed all the way down to the level of the bottom epitaxial layer 130. However, when reforming the bottom contact vias 181 are formed all the way down to the bottom epitaxial layer, as shown in FIGS. 15A and 15C.

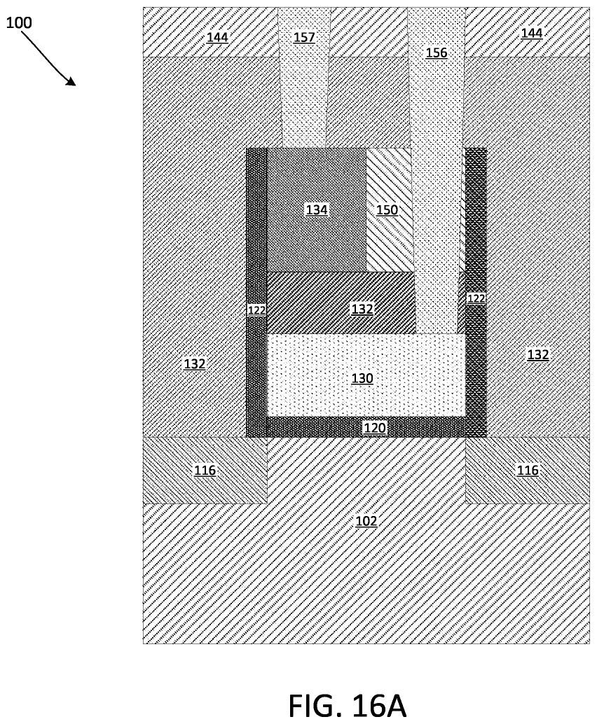

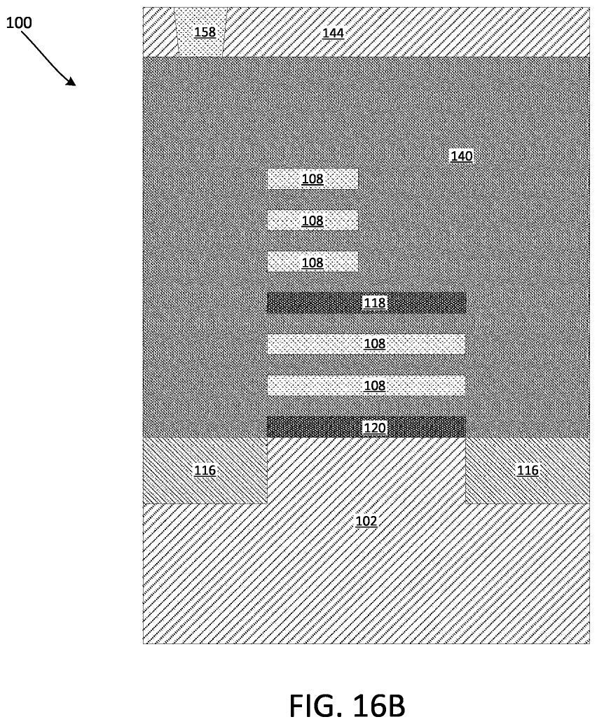

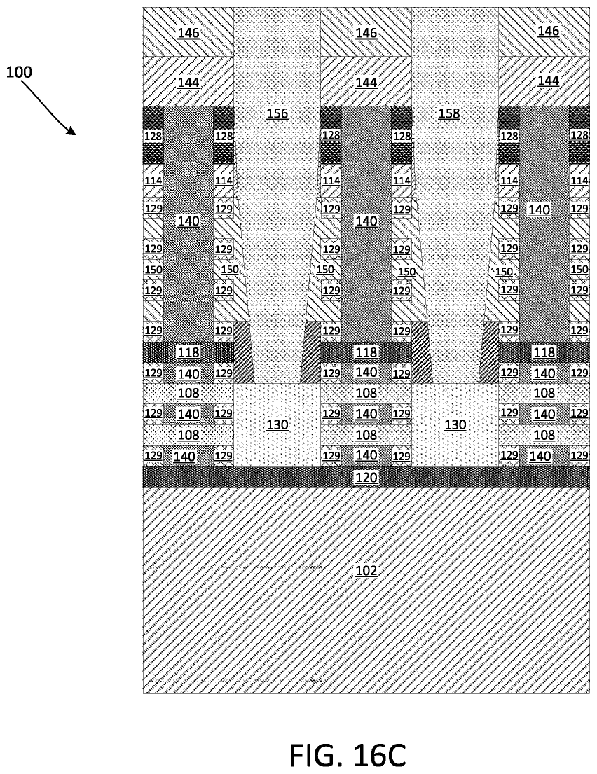

FIGS. 16A, 16B and 16C illustrate the process stage after top S/D contact opening, and gate contact opening formation, followed by contact metallization. Referring now to FIG. 16A, this figure depicts a cross-sectional view of the semiconductor device 100 shown in FIG. 15A taken along line Y1 of FIG. 1B, after additional manufacturing operations, according to embodiments. As shown in FIG. 16A, patterning of the top contact 157 is performed. As shown in FIG. 16B (a cross-sectional view of the semiconductor device 100 shown in FIG. 15B taken along line Y2 of FIG. 1B, after additional manufacturing operations), patterning of the gate contact 158 is performed. After these contact vias are performed, a metallization process is performed to form the bottom contacts 156, the top contacts 157 and the gate contacts 158.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a bottom field effect transistor (FET);
a top FET stacked over the bottom FET, where the top FET has a smaller active area than the bottom FET;
a bottom gate formed in contact with the bottom FET;
a top gate formed in contact with the top FET; and
a bottom contact formed adjacent to the top gate,
wherein an inner spacer is formed between the bottom contact and the top gate.

2. The semiconductor device of claim 1, wherein the bottom FET includes alternating layers of active semiconductor layers and high-κ metal gate layers.

3. The semiconductor device according to claim 2, further comprising a gate spacer surrounding the high-κ metal gate layers.

4. The semiconductor device of claim 3, wherein for the top FET, the gate spacer is formed in contact with the inner spacer.

5. The semiconductor device of claim 3, wherein the gate spacer and the inner spacer are dielectric layers.

6. The semiconductor device according to claim 1, wherein the top FET includes a top epitaxial layer.

7. The semiconductor device according to claim 6, wherein at least a portion of the inner spacer is formed between the bottom contact and the top epitaxial layer.

8. The semiconductor device according to claim 1, wherein an active region of the top FET is laterally offset from an active region of the bottom FET to form a staircase configuration.

9. The semiconductor device according to claim 1, further comprising a hardmask layer in contact with the top gate.

10. The semiconductor device according to claim 9, wherein the hardmask is comprised of a different material than the inner spacer.

11. A method of manufacturing a semiconductor device, the method comprising:
a bottom field effect transistor (FET);
a top FET stacked over the bottom FET, where the top FET has a smaller active area than the bottom FET;
a bottom gate formed in contact with the bottom FET;
a top gate formed in contact with the top FET; and
a bottom contact formed adjacent to the top gate,
wherein an inner spacer is formed between the bottom contact and the top gate.

12. The method of manufacturing a semiconductor device of claim 11, wherein the bottom FET includes alternating layers of active semiconductor layers and high-κ metal gate layers.

13. The method of manufacturing a semiconductor device according to claim 12, further comprising a gate spacer surrounding the high-κ metal gate layers.

14. The method of manufacturing a semiconductor device of claim 13, wherein for the top FET, the gate spacer is formed in contact with the inner spacer.

15. The method of manufacturing a semiconductor device of claim 13, wherein the gate spacer and the inner spacer are dielectric layers.

16. The method of manufacturing a semiconductor device according to claim 11, wherein the top FET includes a top epitaxial layer.

17. The method of manufacturing a semiconductor device according to claim 16, wherein at least a portion of the inner spacer is formed between the bottom contact and the top epitaxial layer.

18. The method of manufacturing a semiconductor device according to claim 11, wherein an active region of the top FET is laterally offset from an active region of the bottom FET to form a staircase configuration.

19. The method of manufacturing a semiconductor device according to claim 11, further comprising a hardmask layer in contact with the top gate.

20. The method of manufacturing a semiconductor device according to claim 19, wherein the hardmask is comprised of a different material than the inner spacer.
